(19) United States
(12) Patent Application Publication
(10) Pub. No.: US 2018/0136390 A1
(43) Pub. Date: May 17, 2018

(54) SEMICONDUCTOR DEVICE AND MANUFACTURING METHOD THEREOF

(71) Applicant: Renesas Electronics Corporation, Tokyo (JP)

(72) Inventors: Shinichi WATANUKI, Ibaraki (JP); Yasutaka NAKASHIBA, Ibaraki (JP)

(73) Assignee: Renesas Electronics Corporation, Tokyo (JP)

(21) Appl. No.: 15/785,560

(22) Filed: Oct. 17, 2017

(30) Foreign Application Priority Data
Nov. 15, 2016 (JP) 2016-222053

(51) Int. Cl. G02B 6/122; H01L 33/62; G02B 6/12

(52) U.S. Cl. CPC G02B 6/122; H01L 33/62; G02B 6/12002; G02B 2006/12197; H01L 2933/0066; H01L 2933/0033; G02B 2006/12126; H01L 2933/0025

(57) ABSTRACT

In a semiconductor device, first dummy patterns including a different material from transmission lines (first optical waveguide and second optical waveguide) are formed in a first region close to the transmission lines, and second dummy patterns, which include the same material as the transmission lines and do not function as the transmission lines, are formed in a second region apart from the transmission lines.

### CROSS-REFERENCE TO RELATED APPLICATIONS

The disclosure of Japanese Patent Application No. 2016-222053 filed on Nov. 15, 2016 including the specification, drawings and abstract is incorporated herein by reference in its entirety.

### BACKGROUND

The present invention relates to a semiconductor device and a manufacturing technique thereof, and to a technique effectively applied, for example, to a semiconductor device including transmission lines represented by an optical waveguide and a wiring and a manufacturing technique thereof.

Japanese Unexamined Patent Application Publication No. 2004-349622 (Patent Document 1) describes a technique in which: dummy electrodes including the same material as a gate electrode are arranged; and dummy patterns including the same material as a sidewall are provided.

Japanese Unexamined. Patent Application. Publication No. Hei 5 (1993)-347365 (Patent Document 2) describes a technique in which dummy wirings including a silicon oxide film are provided.

Japanese Unexamined Patent Application Publication No. 2006-294765 (Patent Document 3) describes a technique in which dummy patterns including a transparent material are arranged in a flattened layer that planarly overlaps a light receiving part.

### RELATED ART DOCUMENTS

### Patent Documents

[Patent Document 1] Japanese Unexamined Patent Application Publication No. 2004-349622

[Patent Document 2] Japanese Unexamined Patent Application Publication No. Hei 5(1993)-347365

[Patent Document 3] Japanese Unexamined Patent Application Publication No. 2006-294765

### SUMMARY

Considering the integration of a plurality of semiconductor devices, it is necessary to multi-layer transmission lines. In this case, it is necessary to flatten an interlayer insulating film existing between the transmission lines, so it is conceivable to arrange dummy patterns. On the other hand, when the transmission lines include, for example, optical waveguides, there is a circumstance in which the dummy patterns cannot be arranged around the optical waveguides in order to suppress light interference caused by proximity patterns. In addition, even when the transmission lines include wirings, constraints are placed on the arrangement of the dummy patterns that may cause parasitic capacitance in order to suppress a delay of a signal transmitted through the wiring. Thus, it is effective to provide dummy patterns for flattening the interlayer insulating film, but from the viewpoint of suppressing light interference and an increase in parasitic capacitance, it is necessary to avoid arranging the dummy patterns in a proximity region of a transmission line including an optical waveguide or a wiring. Therefore, in order to achieve both flattening of the interlayer insulating film and suppression of light interference and an increase in parasitic capacitance, a contrivance on dummy patterns is required.

Other problems and new characteristics will become clear from the description and accompanying drawings of the present specification.

In a semiconductor device in one embodiment, a first pattern including a different material from a transmission line is formed in a first region close to the transmission line, and a second pattern, which includes the same material as the transmission line and does not function as the transmission line, is formed in a second region away from the transmission line.

According to the one embodiment, both flattening of an interlayer insulating film and suppression of light interference and an increase in parasitic capacitance can be achieved.

### BRIEF DESCRIPTION OF THE DRAWINGS

FIG. 1 is a plan view illustrating a semiconductor chip in an embodiment;

FIG. 2 is an enlarged schematic view illustrating an optical waveguide formation region illustrated in FIG. 1;

FIG. 3 is a view schematically illustrating an arrangement example of dummy patterns formed in the optical waveguide formation region;

FIG. 4 is a schematic sectional view taken along the line A-A in FIG. 3;

FIG. 5 is a sectional view illustrating a manufacturing step of a semiconductor device in the embodiment;

FIG. 6 is a sectional view illustrating a manufacturing step of a semiconductor device, following FIG. 5;

FIG. 7 is a sectional view illustrating a manufacturing step of a semiconductor device, following FIG. 6;

FIG. 8 is a sectional view illustrating a manufacturing step of a semiconductor device, following FIG. 7;

FIG. 9 is a sectional view illustrating a manufacturing step of a semiconductor device, following FIG. 8;

FIG. 10 is an enlarged schematic view illustrating a wiring formation region illustrated in FIG. 1;

FIG. 11 is an enlarged schematic view illustrating the wiring formation region illustrated in FIG. 1;

FIG. 12 is a view schematically illustrating an arrangement example of dummy patterns formed in a first wiring layer in the wiring formation region;

FIG. 13 is a view schematically illustrating an arrangement example of dummy patterns formed in a second wiring layer in the wiring formation region;

FIG. 14 is a sectional view taken along the line A-A in FIG. 12 and the line A-A in FIG. 13;

FIG. 15 is a schematic sectional view taken along a section including a light source mounting region illustrated in FIG. 1;

FIG. 16 is a sectional view illustrating a manufacturing step of a semiconductor device in Second Variation; and

FIG. 17 is a sectional view illustrating a manufacturing step of a semiconductor device, following FIG. 16.

### DETAILED DESCRIPTION

When necessary for convenience in the following embodiments, description is given by dividing the embodiment into a plurality of sections or embodiments; however, unless expressly stated otherwise, they are not independent of one another, but one is related with part or the whole of another as a variation, a detail, supplementary description, etc.

When the numbers of elements, etc. (including numbers of pieces, numerical values, amounts, ranges, etc.) are referred to in the following embodiments, the numbers are not limited to the specific ones but may be more or less than the specific numbers, unless expressly stated otherwise or except when the numbers are obviously limited to the specific numbers in principle.

Further, in the following embodiments, it is needless to say that the components (also including constituent steps, etc.) are not necessarily requisite unless expressly stated otherwise or except when they are obviously requisite in principle.

Similarly, when referring to the shapes and positional relations, etc., of components, etc., in the following embodiments, unless expressly stated otherwise or except when they can be thought otherwise in principle, those substantially the same or similar to the shapes, etc., are to be included. This also applies to the above numerical values and ranges.

In addition, like components are denoted with like reference numerals in principle in each of the views for explaining embodiments, and duplicate descriptions are omitted. For easy understanding of drawings, hatching lines may be drawn even in a plan view.

### Study of Improvement

In a semiconductor device that achieves an LSI (Large Scale Integration), a multi-layer wiring structure is adopted in order to miniaturize the semiconductor device. In the steps of forming the multi-layer wiring structure, it is necessary to flatten an area between the wiring layers. This is because when an interlayer insulating film is formed to cover lower layer wirings by using, for example, a CVD (Chemical Vapor Deposition) process, a level difference corresponding to the height of the lower layer wirings is inevitably reflected, whereby an uneven shape is formed in the surface of the interlayer insulating film. When an uneven shape is formed in the surface of the interlayer insulating film, the depth of focus cannot be secured in an exposure step used for patterning upper layer wirings formed over the interlayer insulating film, which causes a patterning defect. Further, also in an etching technique used for forming the upper layer wirings by patterning a conductive film formed over the interlayer insulating film, the thickness of the conductive film becomes large in a level difference portion having an uneven shape, which makes it difficult to etch the conductive film in the level difference portion. Therefore, it becomes necessary to flatten the uneven shape formed in the surface of an interlayer insulating film in order to achieve a multi-layer wiring structure.

As a method of flattening the surface of an interlayer insulating film, a CMP (Chemical Mechanical Polishing) process is widely used. In this CMP process, the accuracy of the flattening decreases as the sparse and dense of the patterns covered with the interlayer insulating film increases. Therefore, in order to increase the accuracy of the flattening, the patterns covered with the interlayer insulating film are made uniform by providing dummy patterns.

Further, the accuracy of wiring processing using etching can also be improved by making the pattern density uniform due to the provision of the dummy patterns. This is because the accuracy of wiring processing using etching is also affected by the sparse and dense of wiring density. Therefore, making wiring density uniform by providing dummy patterns is desirable from both the viewpoints of: improving the accuracy of flattening the surface of an interlayer insulating film by a CMP process; and improving the accuracy of the etching processing of wirings themselves.

However, when the dummy patterns include the same material as the wirings, the following side effects occur. That is, the fact that the dummy patterns include the same conductive material as the wirings means that parasitic capacitance is formed between the wiring and the dummy pattern, and in particular when a high frequency signal is used, a signal delay caused by the parasitic capacitance is revealed as a problem. In particular, in the case of a digital signal in which timing is important, a signal delay may cause a malfunction, so from the viewpoint of suppressing a signal delay by reducing parasitic capacitance, it is desirable that the dummy patterns include an insulating material, not a conductive material. That is, in order to simply improve the accuracy of flattening the surface of the interlayer insulating film by a CMP process, the material of the dummy patterns may be a conductive material or an insulating material, but further taking a reduction in parasitic capacitance into consideration, it is desirable that the dummy patterns include an insulating material. On the other hand, when the dummy patterns include an insulating material, the sparse and dense of wirings can be made uniform, but in etching the wirings, the dummy patterns including an insulating material are formed in a step different from the step of etching the wirings, which does not contribute to an improvement in the accuracy of the etching processing of the wirings.

From the above, when the dummy patterns include the same material as the material of the wirings, the following advantages can be obtained, that is, the accuracy of flattening the surface of the interlayer insulating film can be improved and the accuracy of the etching processing of the wirings can be improved; however, which causes the side effect of increasing parasitic capacitance. On the other hand, when the dummy patterns include an insulating material different from the material of the wirings, the following advantages can be obtained, that is, the accuracy of flattening the surface of the interlayer insulating film can be improved and parasitic capacitance can be reduced; however, which causes the side effect that it becomes difficult to improve the accuracy of the etching processing of the wirings. That is, a contrivance is required to improve the accuracy of flattening the surface of the interlayer insulating film, to reduce parasitic capacitance, and to improve the accuracy of the etching processing of the wirings, by providing dummy patterns.

Further, even with a focus on a silicon photonics technology, a contrivance is required to improve the accuracy of flattening the surface of the interlayer insulating film, to reduce parasitic capacitance, and to improve the accuracy of the etching processing of optical waveguides, by providing dummy patterns. Hereinafter, this point will be described.

In a silicon photonics technology, some optical waveguides are required not to mutually interfere with each other even by light seepage (evanescent light). Therefore, a predetermined interval is required to be secured between optical waveguides in order not to mutually interfere with each other even if light seepage occurs, and the integration degree of optical waveguides tends to be remarkably lower than that of LSIs because the optical waveguides are essentially used for signal transmission between chips (mm to cm level); and due to the synergistic factor of them, the pattern density of optical waveguides becomes extremely low (to 5%). In an optical waveguide, a dummy pattern including silicon that is the same material as the optical waveguide cannot be arranged in the vicinity region of the optical waveguide, from the viewpoint of preventing mutual interference. Therefore, in the silicon photonics technology, there is a circumstance that it is difficult to improve the flatness of the surface of an interlayer insulating film covering optical waveguides due to: that the pattern density of the optical waveguide; themselves is low; and that a dummy pattern including silicon cannot be arranged in the vicinity region of the optical waveguide.

Herein, it can be considered that dummy patterns including, for example, an insulating material are used. In this case, mutual interference can be prevented even if the dummy pattern is arranged near an optical waveguide. Therefore, by arranging dummy patterns including an insulating material also in the vicinity region of an optical waveguide, the flatness of an interlayer insulating film covering the optical waveguides can be improved while preventing mutual interference. Further, a high frequency electric signal is transmitted through the wiring over the interlayer insulating film, the wiring being coupled to a silicon photonics element, but an increase in the parasitic capacitance between the wiring and the dummy patterns can also be suppressed by the dummy patterns including an insulating material. In a silicon photonics technology, an improvement in the accuracy of flattening the surface of an interlayer insulating film, a reduction in parasitic capacitance, and prevention of mutual interference between optical waveguides can be simultaneously achieved by dummy patterns including an insulating material, as described above. However, as a result of forming the dummy patterns from an insulating material different from that of the optical waveguides, the pattern density of the optical waveguides themselves including silicon remains low even if the dummy patterns are used, even in the silicon photonics technology, and hence it is difficult to improve the accuracy of the etching processing of the silicon included in the optical waveguides. In the silicon photonics technology, the scattering of the light transmitted through the optical waveguide particularly becomes large as the accuracy of processing the optical waveguide decreases, and as a result, a loss of light becomes large. From this fact, it is important to improve the accuracy of the etching processing of the optical waveguides in the silicon photonics technology, from the viewpoint of suppressing a loss of light; however, it is difficult to improve the accuracy of the etching processing of the optical waveguides simply by using dummy patterns including an insulating material, as described above.

From the above, it is known that: in the silicon photonics technology, an improvement in the accuracy of flattening the surface of an interlayer insulating film, a reduction in parasitic capacitance, and prevention of mutual interference between the optical waveguides cannot be simultaneously achieved by providing dummy patterns; and hence a contrivance is required to simultaneously achieve these demands.

Therefore, in the present embodiment, with a first focus on optical waveguides in the silicon photonics technology, a contrivance has been made such that an improvement in the accuracy of flattening the surface of an interlayer insulating film, a reduction in parasitic capacitance, prevention of mutual interference between the optical waveguides, and an improvement in the accuracy of the etching processing of the optical waveguides, which are not simultaneously achieved by the present technology even by providing dummy patterns, are simultaneously achieved. Hereinafter, the technical ideas of the embodiment, in which this contrivance has been made, will be described.

### Configuration of Semiconductor Device

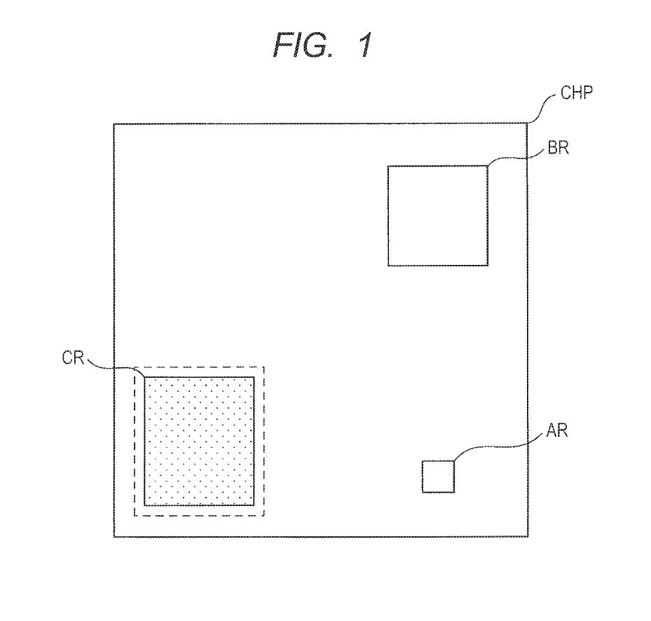

FIG. 1 is a plan view illustrating a semiconductor chip CHP in the present embodiment. As illustrated in FIG. 1, the semiconductor chip CHP in the embodiment has a rectangular planar shape, and has an optical waveguide formation region AR, a wiring formation region BR, and a light source mounting region CR. The optical waveguide formation region AR is a region where optical waveguides including, for example, silicon are formed, and the wiring formation region BR is a region where wirings including, for example, aluminum (including an aluminum alloy) are formed across multiple layers. The light source mounting region CR is a region where a semiconductor device, in which a semiconductor laser including a compound semiconductor such as, for example, GaN is formed, is embedded. As described above, the semiconductor chip CHP in the embodiment includes at least an optical waveguide, a plurality of wirings having a multi-layer wiring structure, and another semiconductor device serving as a light source, and in the semiconductor chip CHP in the embodiment, a configuration in which an optical circuit and an electronic circuit are merged, is achieved by including these components.

### <<Configuration of Optical Waveguide>>

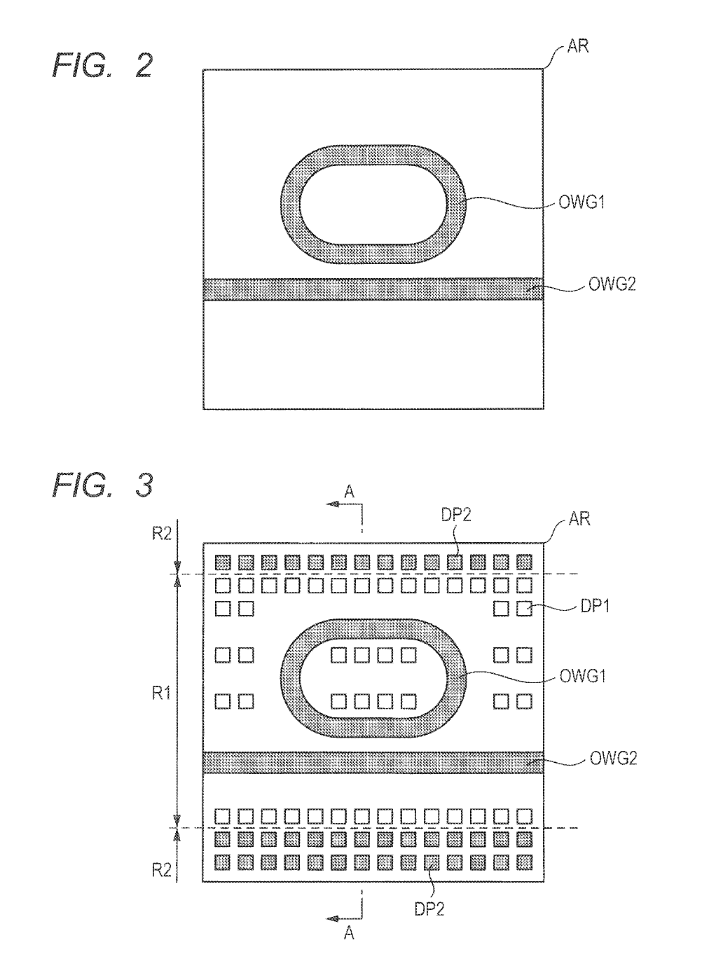

FIG. 2 is an enlarged schematic view illustrating the optical waveguide formation region AR illustrated in FIG. 1. In the optical waveguide formation region AR in the present embodiment, a plurality of optical waveguides including an optical waveguide OWG1 and an optical waveguide OWG2 are formed, as illustrated in FIG. 2. Each of the optical waveguides OWG1 and OWG2 is formed by processing silicon (core layer), and has a structure in which its circumference is surrounded by a silicon oxide film (cladding layer) having a lower refractive index than silicon. Thereby, the light traveling through the inside of each of the optical waveguides OWG1 and OWG2 including silicon is totally reflected at the interface between the silicon (core layer) and the silicon oxide film (cladding layer). As a result, the light traveling through the inside of each of the optical waveguides OWG1 and OWG2 is transmitted without leaking from the i inside of each of them. Actually, however, evanescent light slightly seeping from the silicon toward the silicon oxide film is generated, so that the optical waveguides OWG1 and OWG2 are arranged to be spaced apart from each other by a predetermined distance, as illustrated in FIG. 2, in order that the evanescent light that have respectively seeped may not interfere with each other.

### <<Arrangement of Dummy Pattern>>

In the semiconductor chip CHP in the present embodiment, dummy patterns are formed in the optical waveguide formation region AR illustrated in FIG. 2. Specifically, FIG. 3 is a view schematically illustrating an arrangement example of dummy patterns formed in the optical waveguide formation region AR. In FIG. 3, the optical waveguides OWG1 and OWG2 are formed in the optical waveguide formation region AR so as to be spaced apart from each other by a distance at which they do not interfere with each other. Then, a region R1 close to the optical waveguide OWG1 and a region R2 outside the region R1 are formed. That is, the optical waveguide formation region AR of the semiconductor chip CHP in the embodiment includes, as illustrated in FIG. 3: the optical waveguides OWG1 and OWG2 that are transmission lines for transmitting optical signals; the region R1 within a range of a predetermined distance from the transmission lines in plan view; and the region R2 away from the transmission lines by a distance larger than the predetermined distance in plan view. In this case, a plurality of dummy patterns DP1 are formed in the region R1, while a plurality of dummy patterns DP2 are formed in the region R2, as illustrated in FIG. 3. Specifically, the dummy patterns DP1 including a different material from the transmission lines (the optical waveguides OWG1 and OWG2) are formed in the region R1, while the dummy patterns DP2, which include the same material as the transmission lines and do not function as the transmission lines, are formed in the region R2. For example, the semiconductor chip CHP in the embodiment has an interlayer insulating film including a silicon oxide film and covering the transmission lines, and the refractive index of the dummy pattern DP1 is the same as that of the interlayer insulating film. In addition, the dummy patterns DP1 include the same silicon oxide film as the interlayer insulating film. On the other hand, the dummy patterns DP2 formed in the region. R2 include the same silicon as the transmission lines. As described above, the dummy patterns DP1 and DP2, the materials of which are different from each other, are formed in the optical waveguide formation AR in the embodiment, in which: the dummy patterns DP1 including an insulating material are formed in the region R1 close to the transmission lines; and the dummy patterns DP2 including the same silicon as the transmission lines are formed in the region R2 outside the region R1.

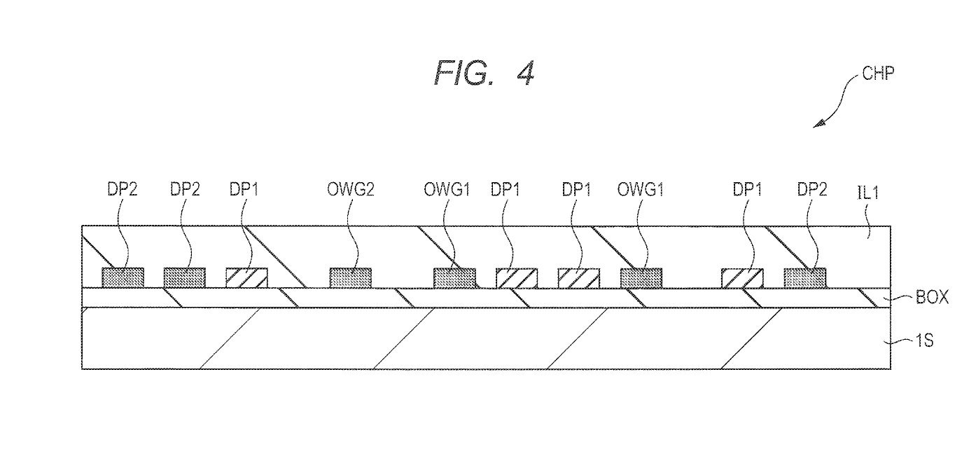

Next, FIG. 4 is a schematic sectional view taken along the line A-A in FIG. 3. In FIG. 4, the semiconductor chip CHP in the present embodiment includes, for example, a support substrate 15 including silicon, a buried insulating layer BOX including silicon oxide formed over the support substrate 1S, and an SOI (Silicon On Insulator) substrate including a silicon layer formed over the buried insulating layer BOX. And as illustrated in FIG. 4, the optical waveguides OWG1 and OWG2 including silicon are formed by processing a silicon layer of the SOI substrate. In particular, the dummy patterns DP2 including silicon are formed in the silicon layer, the same layer as the optical waveguides OWG1 and OWG2, in the embodiment. Further, in the semiconductor chip CHP in the embodiment, the dummy patterns DP2 including, for example, a silicon oxide film are also formed in the same layer as the optical waveguides OWG1 and OWG2 and the dummy patterns DP1. Furthermore, an interlayer insulating film IL1 including, for example, a silicon oxide film is formed to cover the optical waveguides OWG1 and OWG2 and the dummy patterns DP1 and DP2, as illustrated in FIG. 4. In the semiconductor chip CHP in the embodiment, the dummy patterns DP1 are arranged in the region close to the optical waveguides OWG1 and OWG2, while the dummy patterns DP2 are arranged in the region away from the optical waveguides OWG1 and OWG2, as can be seen from FIG. 4. That is, the dummy patterns DP1 are interposed between the transmission lines and the dummy patterns DP2 in the semiconductor chip CHP in the embodiment. In other words, the distance between the transmission line and the dummy pattern DP1 is smaller than that between the transmission line and the dummy pattern DP1. That is, the distance between the transmission line and the dummy pattern DP2 is larger than that between the transmission line and the dummy pattern DP1.

### Characteristics in Embodiment

Subsequently, characteristic points in the present embodiment will be described. A characteristic point in the embodiment can be described as follows: on the premise that the dummy patterns DP1 and DP2, the materials of which are different from each other, are included, the dummy patterns DP1 are arranged in the region R1, vicinity region of the optical waveguides OWG1 and OWG2 that are transmission lines, and the dummy patterns DP2 are arranged in the region R2 farther away from the transmission lines than the region R1, as illustrated, for example, in FIG. 3. In particular, the dummy patterns DP1 include the same insulating material (silicon oxide) as the interlayer insulating film, and the dummy patterns DP2 include the same material (silicon) as the transmission lines, in the embodiment. Thereby, according to the embodiment, an improvement in the accuracy of flattening the surface of the interlayer insulating film, a reduction in parasitic capacitance, prevention of mutual interference between the optical waveguides, and an improvement in the accuracy of the etching processing of the optical waveguides can be simultaneously achieved. Hereinafter, this point will be described.

In the present embodiment, the dummy patterns DP1 and DP2 are provided in the same layer as the optical waveguides OWG1 and OWG2 covered with the interlayer insulating film IL1, as illustrated, for example, in FIG. 4. As a result, the pattern density of the patterns covered with the interlayer insulating film IL1 can be made uniform in the embodiment. That is, in the embodiment, the sparse and dense of the patterns covered with the interlayer insulating film IL1 can be made smaller by providing the dummy patterns DP1 and DP2 than the configuration formed when only the optical waveguides OWG1 and OWG2 are provided, whereby the underlying patterns covered with the interlayer insulating film IL1 can be made uniform. As a result, according to the embodiment, the accuracy of fattening the surface of the interlayer insulating film IL1 by a CMP process can be improved by adding the dummy patterns DP1 and DP2. That is, in the case where the dummy patterns DP1 and DP2 are not provided, the sparse and dense of the underlying patterns covered with the interlayer insulating film IL1 becomes large, so that “dishing” or the like by a CMP process is likely to occur and the flatness of the surface of the interlayer insulating film IL1 is deteriorated. On the other hand, in the embodiment, the pattern density of the underlying patterns covered with the interlayer insulating film IL1 is made uniform by providing the dummy patterns DP1 and DP2 in the same layer as the transmission lines, as illustrated, for example, in FIG. 4. As a result, according to the embodiment, “dishing” or the like is less likely to occur even when the surface of the interlayer insulating film IL1 is polished by a CMP process, whereby the flatness of the surface of the interlayer insulating film IL1 can be improved.

Next, in the present embodiment, the dummy patterns DP1 including an insulating material, which is the same material as the interlayer insulating film IL1, are arranged in the region R1 close to the optical waveguides OWG1 and OWG2, as illustrated, for example, in FIG. 3, not providing the dummy patterns DP2 including silicon that is the same material as the transmission lines. Thereby, according to the embodiment, mutual interference of light can be prevented. That is, if the dummy patterns DP2 including silicon, which is the same material as the transmission lines, are provided in the region R1 within a range of a predetermined distance from the transmission line, light is transmitted also to the inside of the dummy pattern DP2, and hence the evanescent light that has seeped from the transmission line enters also the inside of the dummy pattern DP2 and travels trough the dummy pattern DP2, which causes a loss of light from the transmission line. In addition, the light that has entered the dummy pattern DP2 mutually interferes with the light traveling through the transmission line. In the embodiment, however, the dummy patterns DP1 including an insulating material, which is the same material as the interlayer insulating film IL1, are arranged in the region R1 close to the optical waveguides OWG1 and OWG2, not providing the dummy patterns DP2 including silicon that is the same material as the transmission lines. In this case, the inside of the dummy pattern DP1 does not function as an optical waveguide, and hence a loss of light and mutual interference of light can be suppressed from being caused. As a result, according to the embodiment, the quality of the transmission lines including the optical waveguides OWG1 and OWG2 can be improved.

From the above, in the present embodiment, the dummy patterns DP1 including an insulating material, which is the same material as the interlayer insulating film IL1, are arranged in the region R1 close to the optical waveguides OWG1 and OWG2, as illustrated in FIG. 3, not providing the dummy patterns DP2 including silicon that is the same material as the transmission lines, whereby a loss of light (including mutual interference of light) can be reduced.

Further, in the present embodiment, the dummy patterns DP2 including silicon, which is the same material as the transmission lines, are arranged in the region R2 outside the region R1, as illustrated, for example, in FIG. 3, not arranging the dummy patterns DP1 including an insulating material that is the same material as the interlayer insulating film IL1. Thereby, according to the embodiment, the accuracy of processing the optical waveguides OWG1 and OWG2 including silicon can be improved. There is no problem if the dummy patterns DP1 including the same insulating material as the interlayer insulating film IL1 are provided also in the region R2, from the viewpoint of, for example, improving the flatness of the surface of the interlayer insulating film IL1. In this case, however, when the silicon layer of the SOI substrate, in which the optical waveguides OWG1 and OWG2 are formed, is processed, the dummy patterns DP1 including an insulating material are processed in another step, and the pattern density of the transmission lines including the optical waveguides OWG1 and OWG2 remains low. Regarding this point, if the dummy patterns DP2 including silicon, which is the same material as the transmission lines, are arranged in the region R1 within a range of a predetermined distance from the transmission lines in order to increase the pattern density of the transmission lines, mutual interference of light and a loss of light, which result from light seepage, may be caused and parasitic capacitance may also be increased, so it is difficult to adopt this configuration. Therefore, in the embodiment, the dummy patterns DP2 including silicon, which is the same material as the transmission lines, are arranged in the region R2 outside the region R1, not arranging the dummy patterns DP1 including an insulating material that is the same material as the interlayer insulating film IL1. In this case, the dummy patterns DP2 to be processed in the same step as the transmission lines are provided in the region R2, and hence the pattern density in the silicon layer of the SOI substrate can be increased by combining the transmission lines, including the optical waveguides OWG1 and OWG2, with the dummy patterns DP2. As a result, according to the embodiment, the accuracy of processing the silicon layer of the SOI substrate can be improved. The fact that the accuracy of processing the silicon layer can be improved means that the accuracy of processing the optical waveguides OWG1 and OWG2 that are transmission lines can be improved, whereby the performance of the optical waveguides OWG1 and OWG2 as transmission lines can be improved.

Herein, the dummy patterns DP2, which may cause mutual interference of light and a loss of light resulting from light seepage, are formed in the present embodiment, but it is important that they are formed in the region R2 away from the transmission lines, not in the region R1 close to the transmission lines. That is, if the dummy patterns DP2 including silicon, which is the same material as the transmission lines, are arranged in the region R1 close to the transmission lines, mutual interference of light and a loss of light resulting from light seepage become obvious, but they do not become obvious even when the dummy patterns DP2 are arranged in the region R2 away from the transmission lines. This is because the light seepage from the transmission lines occurs in the region R1 close to the transmission lines, but the light seepage does not reach the region R2 away from the transmission lines. That is, mutual interference of light and a loss of light resulting from light seepage do not become obvious in the region R2, and hence in the embodiment, the dummy patterns DP2 including silicon, which is the same material as the transmission lines, are arranged in the region R2, whereby the pattern density in the silicon layer of the SOI substrate is increased.

As described above, according to the characteristic points in the present embodiment, a remarkable advantage can be obtained in which an improvement in the accuracy of flattening the surface of the interlayer insulating film, a reduction in parasitic capacitance, prevention of mutual interference between the optical waveguides, and an improvement in the accuracy of the etching processing of the optical waveguides can be simultaneously achieved.

### Manufacturing Method of Semiconductor Device

A semiconductor device in the present embodiment is configured as described above, and hereinafter a manufacturing method thereof will be described with reference to the drawings.

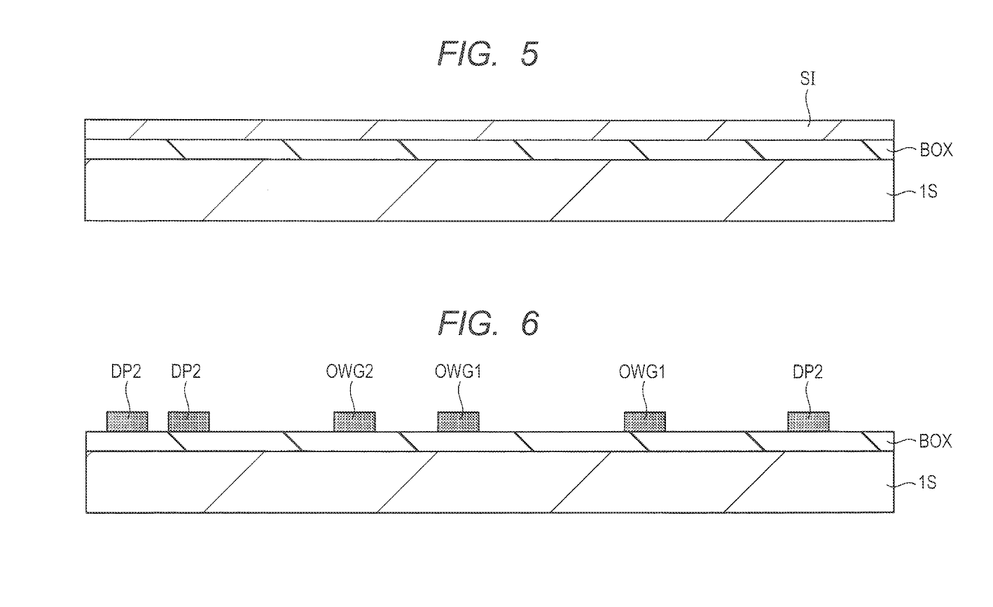

First, an SOI substrate including the support substrate 1S, the buried insulating layer BOX formed over the support substrate 1S, and the silicon layer (semiconductor layer) SI formed over the buried insulating layer BOX is provided, as illustrated in FIG. 5. Next, the silicon layer SI is patterned by using a photolithography technique and an etching technique, as Illustrated in FIG. 6. Specifically, the optical waveguides OWG1 and OWG2 are formed in the optical waveguide formation region, and the dummy patterns DP2 are formed in a region (second region) away from the optical waveguides OWG1 and OWG2 by a distance larger than a first predetermined distance. That is, the dummy patterns DP2 are formed in the same layer as the optical waveguides OWG1 and OWG2 in the present embodiment. As described above, not only the optical waveguides OWG1 and OWG2 but also the dummy patterns DP2 are processed when the silicon layer SI is patterned, in the present embodiment, and hence the pattern density in the silicon layer of the SOI substrate is increased by combining the transmission lines, including the optical waveguides OWG1 and OWG2, with the dummy patterns DP2. As a result, according to the embodiment, the accuracy of processing the silicon layer of the SOI substrate can be improved. The fact that the accuracy of processing the silicon layer can be improved means that the accuracy of processing the optical waveguides OWG1 and OWG2 that are transmission lines can be improved, whereby the performance of the optical waveguides OWG1 and OWG2 as transmission lines can be improved.

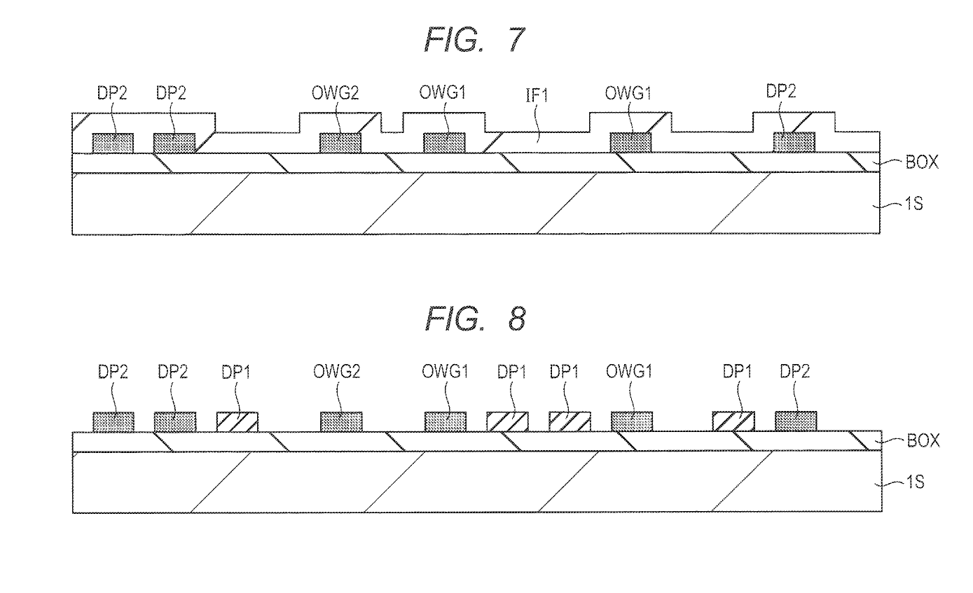

Subsequently, the insulating film IF1 is formed over the SOI substrate, the silicon layer SI of which has been processed, as illustrated in FIG. 7. The insulating film IF1 includes, for example, a silicon oxide film, and can be formed by using a CVD process. Then, the insulating film IF1 is patterned by using a photolithography technique and an etching technique, as illustrated in FIG. 8. Specifically, the dummy patterns DP1 including a material (silicon oxide film), which s different from that of the optical waveguides OWG1 and OWG2, are formed in a region (first region) within the first predetermined distance from the optical waveguides OWG1 and OWG2

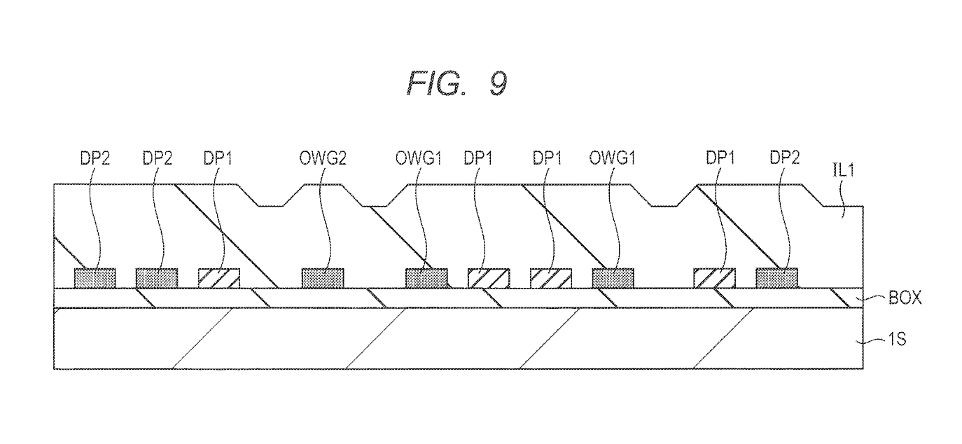

Next, the interlayer insulating film IL1 including, for example, a silicon oxide film is formed over the SOI substrate, as illustrated an FIG. 9. This interlayer insulating film IL1 can be formed by using, for example, a CVD process. The interlayer insulating film IL1 formed as described above in the present embodiment includes a material having the same refractive index as the dummy patterns DP1. In addition, the interlayer insulating film IL1 formed in the embodiment includes the same material as the dummy patterns DP1.

In the present embodiment, the interlayer insulating film IL1 is formed to cover the optical waveguides OWG1 and OWG2 and the dummy patterns DP1 and DP2, as described above. Thereafter, the surface of the interlayer insulating film is flattened by using, for example, a CMP process. In this case, the dummy patterns DP1 and DP2 are provided in the same layer as the optical waveguides OWG1 and OWG2 covered with the interlayer insulating film IL1, in the embodiment, as illustrated, for example, in FIG. 9. As a result, in the embodiment, the sparse and dense of the patterns covered with the interlayer insulating film IL1 can be made smaller by providing the dummy patterns DP1 and DP2 than the configuration formed when only the optical waveguides OWG1 and OWG2 are provided, whereby the underlying patterns covered with the interlayer insulating film IL1 can be made uniform. According to the embodiment, the accuracy of flattening the surface of the interlayer insulating film IL1 by a CMP process can be improved by adding the dummy patterns DP1 and DP2. The optical waveguides OWG1 and OWG2 in the embodiment can be manufactured as described above.

### First Variation

### <<Configuration in First Variation>>

Subsequently, First Variation will be described. In First Variation, an example will be described in which technical ideas in the embodiment are applied with a focus placed on transmission lines including wirings for transmitting electric signals.

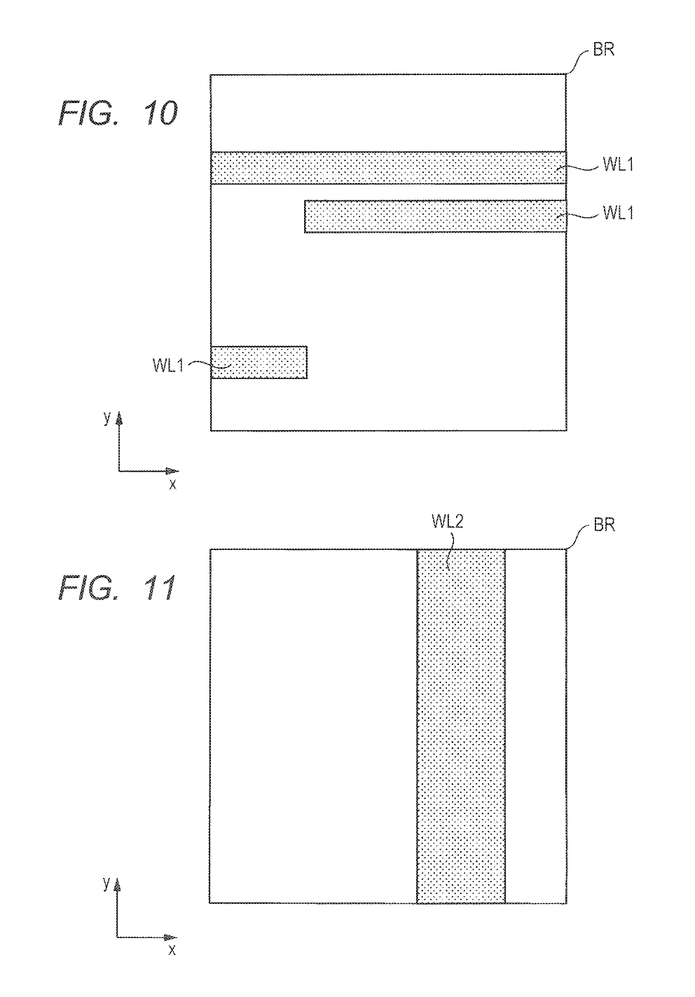

FIG. 10 is an enlarged schematic view illustrating the wiring formation region illustrated in FIG. 1, and illustrates the layout configuration of a first layer wiring WL1. Specifically, a plurality of the first layer wirings WL1 are formed to extend in an x direction, as illustrated in FIG. 10. On the other hand, FIG. 11 is an enlarged schematic view illustrating the wiring formation region BR illustrated in FIG. 1, and illustrates the layout configuration of a second layer wiring WL2. Specifically, the second layer wiring WL2 is formed to extend in a y direction crossing the x direction, as illustrated in FIG. 11. Therefore, it can be seen that the first layer wirings WL1 and the second layer wiring WL2 extend in directions crossing each other in plan view, as illustrated in FIGS. 10 and 11.

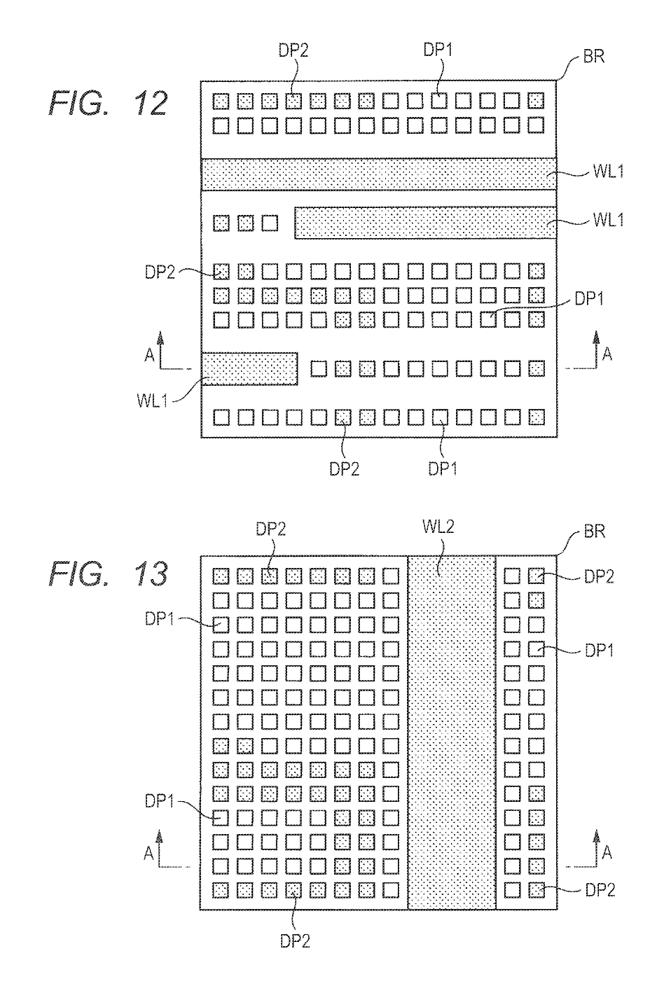

In the present embodiment, dummy patterns are formed in the first wiring layer in the wiring formation region BR illustrated in FIG. 10, and dummy patterns are also formed in the second wiring layer in the wiring formation region BR illustrated in FIG. 11. Specifically, FIG. 12 is a view schematically illustrating an arrangement example of the dummy patterns formed in the first wiring layer in the wiring formation region BR. FIG. 13 is a view schematically illustrating an arrangement example of the dummy patterns formed in the second wiring layer in the wiring formation region BR.

Also in the present variation illustrated in FIGS. 12 and 13, dummy patterns DP1 including a different material from the first layer wiring WL1 and dummy patterns DP2 including the same material as the first layer wiring WL1 are formed in the same layer as the first layer wiring WL1. Because the first layer wiring WL1 includes, for example, an aluminum wiring, the dummy patterns DP2 also include an aluminum material. On the other hand, the dummy patterns DP1 including a different material from the first layer wiring WL1 include, for example, silicon oxide, and hence it can be said that the dummy patterns DP1 include the same material as the interlayer insulating film.

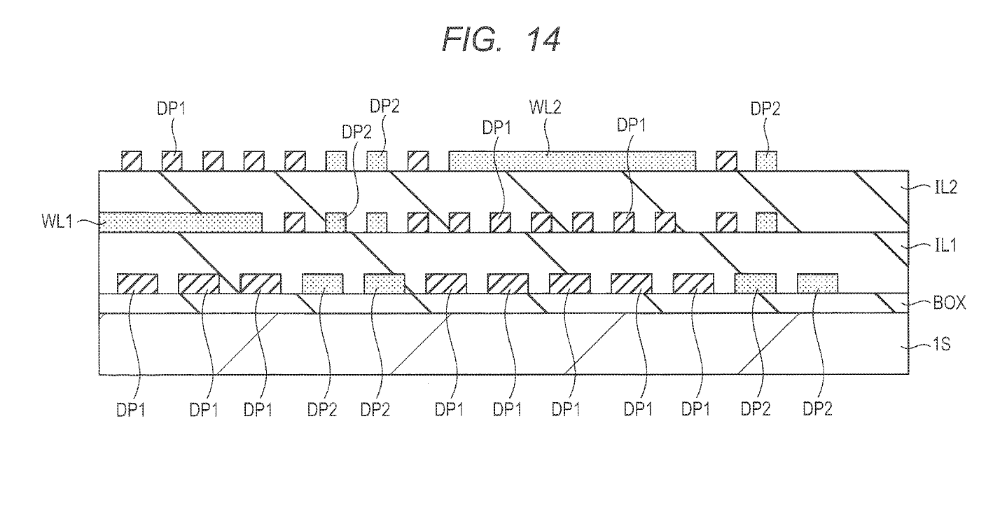

FIG. 14 is a sectional view taken along the line A-A in FIG. 12 and the line A-A in FIG. 13. In First Variation, a buried insulating layer BOX is formed over a support substrate 15, and the dummy patterns DP1 and DP2 are formed in the same layer as the optical waveguide in the embodiment, as illustrated in FIG. 14, by processing a silicon layer formed over the burred insulating layer BOX. In First Variation, the first layer wiring WL1 is formed over an interlayer insulating film IL1, and the dummy patterns DP1 and DP2 are formed in the same layer as the first layer wiring WL1, as illustrated in FIG. 14. Further, in First Variation, an interlayer insulating film IL2 including, for example, a silicon oxide film is formed to cover the first layer wiring WL1 and the dummy patterns DP1 and DP2, and over the interlayer insulating film IL2, the second layer wiring WL2 and the dummy patterns DP1 and DP2, the latter two being formed in the same layer as the second layer wiring WL, are formed.

### <<Characteristics in First Variation>>

A characteristic point in First Variation configured as described above is that the dummy patterns DP1 and DP2 are arranged in the same layer as the first layer wiring WL1, as illustrated, for example, in FIG. 14. Thereby, according to First Variation, the pattern density of the first wiring layer including the first layer wiring WL1 can be made uniform by providing the dummy patterns DP1 and DP2. As a result, according to First Variation, the accuracy of flattening the surface of the interlayer insulating film IL2 by a CMP process can be improved by adding the dummy patterns DP1 and DP2. Also in First Variation, a reduction in parasitic capacitance can be particularly achieved by arranging the dummy patterns DP1 including an insulating material (silicon oxide film), which is the same material as the interlayer insulating film IL2, in a region close to the first layer wiring WL1, as illustrated in FIG. 14, not providing the dummy patterns DP2 including an aluminum material that is the same material as the first layer wiring WL1.

Further, also in First Variation, not only the dummy patterns DP1 including an insulating material, which is the same material as the interlayer insulating film IL2, but also the dummy patterns DP2 including aluminum, which is the same material as the transmission lines, are arranged as illustrated, for example, in FIG. 14. Thereby, according to First Variation, the accuracy of processing the first layer wiring WL1 can be improved.

In First Variation, a technical significance of providing the dummy patterns DP2 including the same material as the first layer wiring WL1 and the dummy patterns DP1 including the same material as the interlayer insulating film IL2 in combination with each other, as described above, is that a reduction in parasitic capacitance by the dummy patterns DP1 and an improvement in the accuracy of processing the first layer wiring WL1 by the dummy patterns DP2 can be achieved. Further, the flatness of the interlayer insulating film IL2 by a CMP process can be improved by providing the dummy patterns DP1 and DP2.

In First Variation, the dummy patterns DP1 and DP2 are further arranged in the same layer as the second layer wiring WL2, as illustrated, for example, in FIG. 14. Thereby, according to First Variation, the pattern density of the second wiring layer including the second layer wiring WL2 can be made uniform by providing the dummy patterns DP1 and DP2. Also in First Variation, a reduction in parasitic capacitance can be particularly achieved by arranging the dummy patterns DP1 including an insulating material (silicon oxide film), which is the same material as the interlayer insulating film IL2, in a region close to the second layer wiring WL2, as illustrated in FIG. 14, not providing the dummy patterns DP2 including an aluminum material that is the same material as the second layer wiring WL2.

Further, also in First Variation, not only the dummy patterns DP1 including an insulating material, which is the same material as the interlayer insulating film IL2, but also the dummy patterns DP2 including aluminum, which is the same mater al as the transmission lines, are arranged as illustrated, for example, in FIG. 14. Thereby, according to First Variation, the accuracy of processing the second layer wiring WL2 can be improved.

Further, regarding a combination arrangement of the dummy patterns DP1 and DP2, not only two-dimensional contrivances in the first wiring layer and the second wiring layer but also a three-dimensional contrivance focusing on the relationship between the first wiring layer and the second wiring layer are made in First variation. That is, in First variation, the dummy patterns DP2 formed in the first wiring layer and the second layer wiring WL2 formed in the second wiring layer are formed so as not to planarly overlap each other, as illustrated in FIG. 14. In other words, the dummy patterns DP1 formed in the first wiring layer and the second layer wiring WL2 formed in the second wring layer are formed to planarly overlap each other.

For example, if the dummy patterns DP2 formed in the first wiring layer and the second layer wiring WL2 formed in the second wiring layer are arranged to planarly overlap each other, parasitic capacitance is formed between the dummy patterns DP2 and the second layer wiring WL2 because the dummy patterns DP2 include a conductive material represented by an aluminum material. Therefore, in First Variation, the dummy patterns DP2 formed in the first wiring layer and the second layer wiring WL2 formed in the second wiring layer are arranged so as not to planarly overlap each other, focusing on a reduction in the parasitic capacitance between the first wiring layer and the second wiring layer. In this case, the dummy patterns DP1 formed in the first wiring layer and the second layer wiring WL2 formed in the second wiring layer are formed to planarly overlap each other, as illustrated in FIG. 14. However, the dummy patterns DP1 include an insulating material, not a conductive material, and hence the parasitic capacitance is not increased even when the dummy patterns DP1 are arranged to planarly overlap the second layer wiring WL2 formed in the second wiring layer. Accordingly, the parasitic capacitance is reduced in First Variation by adopting not only two-dimensional contrivances in the first wiring layer and the second wiring layer but also a three-dimensional contrivance focusing on the relationship between the first wiring layer and the second wiring layer. Thereby, according to First Variation, a signal delay of the electric signals transmitted through the first layer wiring WL1 and the second layer wiring WL2 can be effectively suppressed, whereby a malfunction of an electric circuit can be prevented. Further, the parasitic capacitance between the wirings and the optical waveguides can be reduced by forming dummy patterns in consideration of three-dimensional overlap, in which even the dummy patterns formed in the silicon layer SI include the same material as the interlayer insulating film IL1 in an area where the first layer wiring WL1 and the second layer wiring WL2 overlap each other, even when the area is away form the optical waveguides OWG1 and OWG2, and the like.

### <<Manufacturing Method in First Variation>>

Next, a manufacturing method of a semiconductor device in First Variation will be described with reference to FIG. 14. In FIG. 14, after the manufacturing steps of a semiconductor device in the present embodiment are performed (see FIGS. 5 to 9), an aluminum film (conductive film) is formed over the flattened surface of the interlayer insulating film IL1 by using, for example, a sputtering process.

Subsequently, the aluminum film is patterned by using a photolithography technique and an etching technique. Thereby, the first layer wiring WL1 is formed in the first wiring layer of the wiring formation region BR, and the dummy patterns DP2 are formed in a region (fourth region) away from the first layer wiring WL1 by a distance larger than a second predetermined distance. Thereafter, an insulating film is formed to cover the first layer wiring WL1 and the dummy patterns DP2, by using, for example, a CVD process. Then, the dummy patterns DP1 including the same material as the interlayer insulating film IL1 are formed in a region (third region) within the second predetermined distance from the first layer wiring WL1 by using a photolithography technique and an etching technique.

Next, the interlayer insulating film IL2 including, for example, a silicon oxide film is formed to cover the first layer wiring WL1 and the dummy patterns DP1 and DP2 that are formed in the same layer. Thereafter, the surface of the interlayer insulating film IL2 is flattened by using, for example, a CMP process. Thereafter, the second layer wiring WL2 and the dummy patterns DP1 and DP2, the latter two being formed in the same layer as the second layer wiring WL2, are formed by similar steps. The semiconductor device in First Variation can be manufactured as described above.

### Second Variation

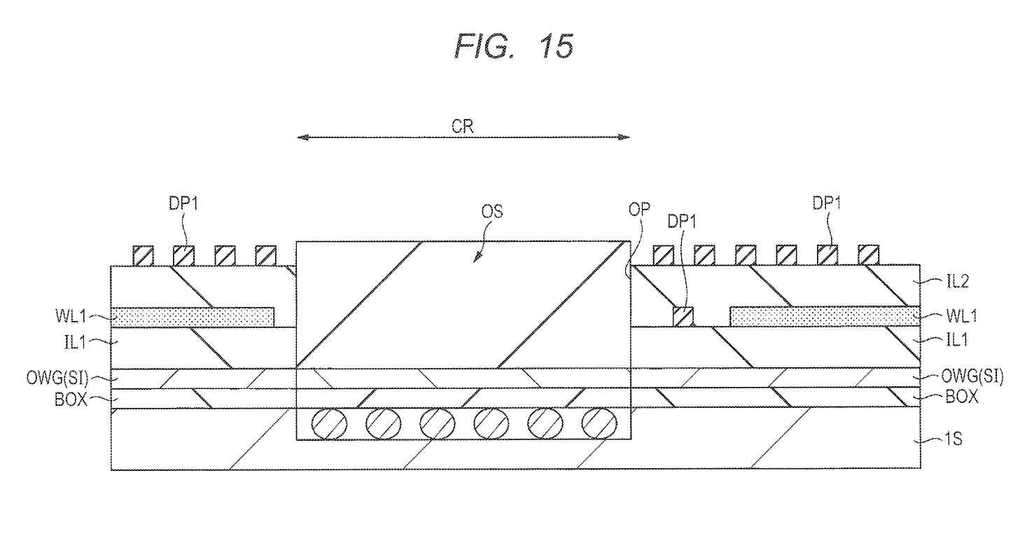

Subsequently, Second Variation will be described. FIG. 15 is a schematic sectional view taken along a section including the light source mounting region CR illustrated in FIG. 1. As illustrated in FIG. 15, an opening OP is formed in the light source mounting region CR of an SOI substrate having an optical waveguide OWG formed by processing the silicon layer SI, a first wiring layer including the first layer wiring WL1, and a second wiring layer formed in the upper layer of the first wiring layer. A light source OS including another semiconductor component is arranged to be embedded in the opening OP. It is configured that the light emitted from the light source OS is transmitted to the optical waveguide OWG. The light source OS includes, for example, a semiconductor laser formed by using a compound semiconductor represented by GaN.

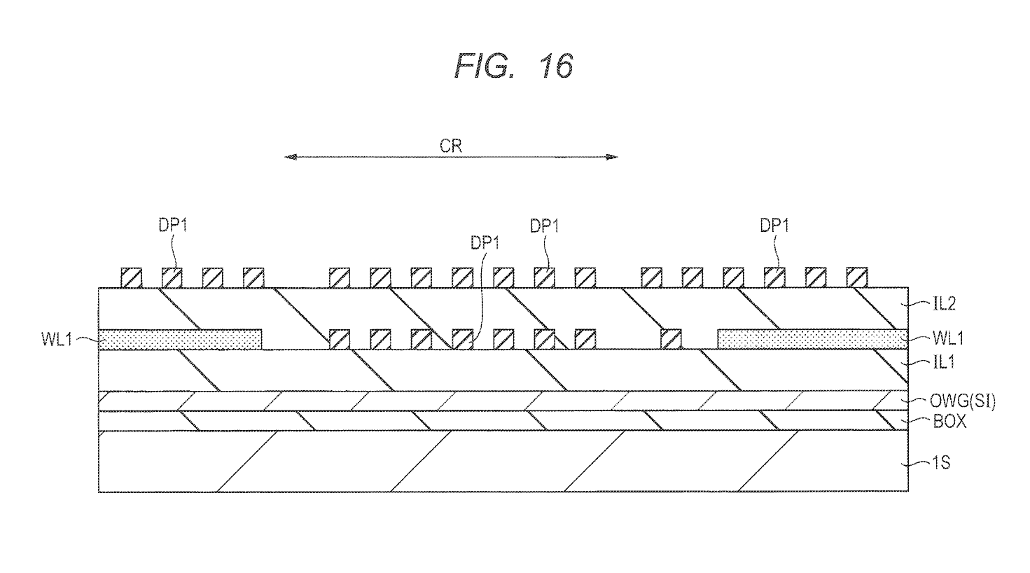

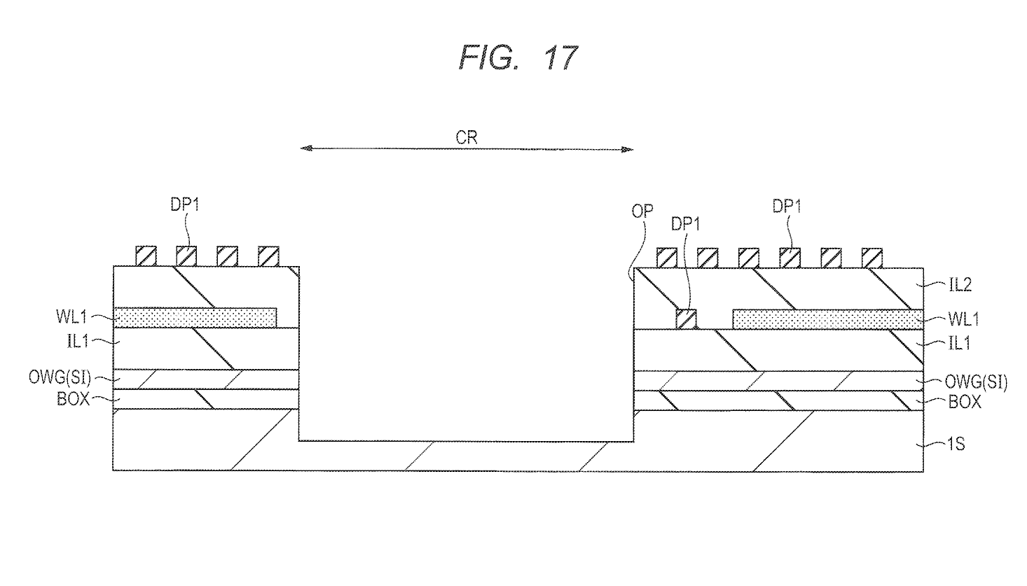

Next, a manufacturing method of a semiconductor device in Second Variation will be described. FIG. 16 is a sectional view illustrating a vicinity region of the light source mounting region CR after the manufacturing steps of a semiconductor device in First Variation have been performed (see FIG. 14). In the light source mounting region CR, only the dummy patterns DP1 including the same insulating material as the interlayer insulating films IL1 and IL2 are formed, and the first layer wiring WL1 (including the second layer wiring) and the dummy patterns DP2 including an aluminum material are not formed, as illustrated in FIG. 16.

Thereafter, an opening OP, which penetrates the second wiring layer and the first wiring layer to reach the SOI substrate, is formed in the light source mounting region CR by using a photolithography technique and an etching technique. In this case, the dummy patterns formed in the light source mounting region CR are only the dummy patterns DP1 including the same insulating material as the interlayer insulating films IL1 and IL2. That is, wirings (the first layer wiring WL1 and the second layer wiring) and the dummy patterns DP2, which include an aluminum material different from the material of the interlayer insulating films IL1 and IL2, are not formed in the light source mounting region CR. Therefore, according to Second Variation, the dummy patterns DP1 can also be etched by the etching targeting the interlayer insulating films IL1 and IL2, and hence the opening OP can easily be formed in the light source mounting region CR. That is, in Second Variation, the dummy patterns DP2 including a different material from the interlayer insulating films IL1 and IL2 are not present in a region that planarly overlaps the light source mounting region CR, and hence the opening OP can easily be formed.

On the other hand, also in Second Variation, a plurality of the dummy patterns DP1 are formed in the first wiring layer and the second wiring layer, and hence the advantage that the flatness of the interlayer insulating film IL2 by a CMP process can be improved can be obtained. That is, according to Second Variation, not only the flatness of the interlayer insulating film IL2 can be improved, but also the easiness of processing the opening OP can be improved, whereby the easiness of mounting the light source OS in the light source mounting region CR can be improved.

The invention made by the present inventors has been specifically described above based on its preferred embodiments, but it is needless to say that the invention should not be limited to the embodiments and may be modified variously within a range not departing from the gist thereof.

What is claimed is:

1. A semiconductor device comprising:
a transmission line;
a first region within a predetermined distance from the transmission line in plan view; and
a second region away from the transmission line by a distance larger than the predetermined distance in plan view,
wherein a first pattern including a different material from the transmission line is formed in the first region, and
wherein a second pattern, which includes the same material as the transmission line and does not function as the transmission line, is formed in the second region.

2. The semiconductor device according to claim 1, having an interlayer insulating film that covers the transmission line,
wherein a refractive index of the first pattern is the same as that of the interlayer insulating film.

3. The semiconductor device according to claim 2,
wherein the first pattern includes the same material as the interlayer insulating film.

4. The semiconductor device according to claim 1,
wherein the transmission line is an optical waveguide that transmits an optical signal.

5. The semiconductor device according to claim 1,
wherein the transmission line is a wiring that transmits an electric signal.

6. The semiconductor device according to claim 1, having:
an interlayer insulating film formed over the transmission line; and
a wiring formed over the interlayer film, wherein the wiring is formed at a position that does not overlap the second pattern in plan view.

7. The semiconductor device according to claim 1, having:
a light source,
wherein the second pattern is not formed in a region that overlaps the light source in plan view.

8. A manufacturing method of a semiconductor device, comprising the steps of:
(a) providing an SOI substrate including a support substrate, a buried insulating layer formed over the support substrate, and a semiconductor layer formed over the buried insulating layer;
(b) forming an optical waveguide in an optical waveguide formation region by patterning the semiconductor layer, and forming a second pattern in a second region apart from the optical waveguide by a distance larger than a first predetermined distance;
(c) forming a first pattern including a different material from the optical waveguide in a first region within the first predetermined distance from the optical waveguide;
(d) forming a first interlayer insulating film so as to cover the optical waveguide, the first pattern, and the second pattern; and
(e) flattening a surface of the first interlayer insulating film.

9. The manufacturing method of a semiconductor device according to claim 8,
wherein the first interlayer insulating film formed in the step (d) includes a material having the same refractive index as the first pattern.

10. The manufacturing method of a semiconductor device according to claim 9,
wherein the first interlayer insulating film formed in the step (d) includes the same material as the first pattern.

11. The manufacturing method of a semiconductor device according to claim 8,
wherein a CMP (chemical mechanical polishing) process is used in the step (e).

12. The manufacturing method of a semiconductor device according to claim 8, comprising the steps of:
(f) after the step (e), forming a conductive film over the first interlayer insulating film;
(g) after the step (f), forming a wiring in a wiring formation region and forming a fourth pattern in a fourth region apart from the wiring by a distance larger than a second predetermined distance, by patterning the conductive film;
(h) after the step (g), forming a third pattern including the same material as the first pattern in a third region within the second predetermined distance from the wiring;
(i) after the step (h), forming a second interlayer insulating film so as to cover the wiring, the third pattern, and the fourth pattern; and)
(j) after the step (i), flattening a surface of the second interlayer insulating film.

13. The manufacturing method of a semiconductor device according to claim 12, having the steps of:
(k) after the step (j), forming an opening in a light source mounting region; and
(l) after the step (k), mounting a light source in the opening.

14. The manufacturing method of a semiconductor device according to claim 13,
wherein the optical waveguide, the second pattern, the wiring and the fourth pattern are not formed in a region that overlaps the light source mounting region in plan view.

15. The manufacturing method of a semiconductor device according to claim 14,
wherein the first pattern and the third pattern are formed in the region that overlaps the light source mounting region in plan view.
